(19) United States
(12) Patent Application Publication
(10) Pub. No.: US 2016/0322265 A1
(43) Pub. Date: Nov. 3, 2016

(54) METHOD AND APPARATUS FOR DETECTION OF FAILURES IN UNDER-FILL LAYERS IN INTEGRATED CIRCUIT ASSEMBLIES

(71) Applicant: GLOBALFOUNDRIES Inc., Grand Cayman, KY (US)

(72) Inventors: Shan GAO, Malta, NY (US); Sukeshwar KANNAN, Malta, NY (US)

(21) Appl. No.: 14/700,639

(22) Filed: Apr. 30, 2015

(51) Int. Cl. H01L 21/66; G01R 31/28; H01L 49/02; G01R 31/02

(52) U.S. Cl. CPC H01L 22/14; G01R 31/025; G01R 31/2896; H01L 22/34; H01L 28/40

(57) ABSTRACT

A methodology and circuitry enabling detection of smaller and early stages of failures in under-fill layers in IC chip assemblies are disclosed. Embodiments include providing a top plate having an upper surface and a lower surface, the lower surface bonded by a bonding material layer to an upper surface of a bottom plate; forming transmitter and receiver asymmetric coupling capacitors between the top plate and the bottom plate; forming a transmission line in the bottom plate connecting elements of the transmitter and receiver asymmetric coupling capacitors in the bottom plate; and detecting a failure in the bonding material layer based, at least in part, on electrical characteristics associated with the transmitter asymmetric coupling capacitor, the receiver asymmetric coupling capacitor, the transmission line or a combination thereof.

### TECHNICAL FIELD

The present disclosure relates generally to designing and fabricating integrated circuit (IC) devices. The present disclosure is particularly applicable to detecting defects/failure in bonding/underfill layers utilized to secure/bond various layers of silicon to each other or to a substrate layer in 28 nanometer (nm), 20 nm and 14 nm technology nodes and beyond.

### BACKGROUND

Generally, in semiconductor device manufacturing, an IC chip/die that includes a plurality of devices (e.g., transistors, diodes, etc.) may be encased in a final package (e.g., plastic casing) to prevent damage to the chip. Also, a chip may be used as a bare die (e.g., flip-chip) for direct placement onto a printed circuit board (PCB) of an electronic device. A plurality of chips may be stacked to form 2.5-dimensional (2.5D) or a 3-dimensional (3D) IC chip stack, which may then be packed into a final package. Usually, a bonding/under-fill material layer is utilized to secure a single chip to a substrate or multiple chips to each other and then onto the substrate in a final package.

FIGS. 1A and 1B schematically illustrate examples of IC devices including an IC chip bonded to a substrate. FIG. 1A illustrates an example of a 3D IC chip stack 100 that includes IC chips 101, 103, and 105. These chips are interconnected by interconnecting elements 107 (e.g., including micro-bumps) to form a vertical stack, which is then connected to a packaging substrate 109 that includes connecting elements 111 (e.g., a ball grid array (BGA)) for connection to a PCB. As illustrated, the IC chips 101 and 103 may include a front/top metal layer 113 and a back/bottom metal layer 115, but the IC chip 105 includes only a front metal layer 113, wherein each of the metal layers 113 and 115 may represent a plurality of metal layers M-1 through M-n. Additionally, the IC chips 101, 103, and 105 include a silicon layer 117, which includes various IC elements and circuits. For stability, an under-fill layer 119 may be used in the spaces between the IC chips 101, 103, and 105 as well as in the space between the IC chip 101 and the substrate 109. In a scenario where there is only one chip (e.g., 101) in the IC package, the under-fill layer 119 would be between the lower surface of the chip 101 and the upper surface of the substrate 109. In a scenario where a chip is mounted directly (e.g., flip-chip) onto a PCB, the under-fill layer would be in the space between the chip and the PCB. Use of advance technologies in assembly and packaging processes for 2D/2.5D/3D or flip-chip applications gives rise to various issues/defects associated with the under-fill layer. For example, the issues may include void areas where there is insufficient or no under-fill material, cracks in the under-fill layer, delamination of the under-fill material layer from a silicon layer or a substrate layer having various surface finish conditions or the like issues, wherein the failures may be due to heat/stress of various packaging and integration processes. FIG. 1B illustrates another example IC device where an under-fill layer 119 is used to bond a chip 101 to a substrate 109. In this example, additional test and interface circuitry 121 for detecting failures in the under-fill layer 119 may be implemented in the chip 101 and the substrate 119; however, such circuitry will increase the interconnect density in the chip and the substrate reducing functional routing space in both. Additionally, testing for continued connectivity using direct current (DC) may not be reliable since failures (e.g., voids, cracks, etc.) in an under-fill layer will affect electrical measurements (e.g., leakage current) used in detecting the failures.

Current methods, such as taking an x-ray of an IC device, use of infrared microscopes, or testing for connection continuity to detect failures in an under-fill layer may be useful in detecting catastrophic failures or defects in under-fill layers in IC structures that are not fully packaged yet. The available methods may be unable to provide sufficient resolution and/or may be very slow for detecting a failure. Thus, such methods may not be effective in detecting smaller or early stages of failures in the under-fill layers.

Therefore, there is a need for a methodology and circuitry enabling detection of smaller and early stages of failures in the under-fill layers in various IC chip assemblies.

### SUMMARY

An aspect of the present disclosure is a method for implementation of a circuit in an IC device for measuring various electrical parameters for detecting smaller and early stages of failures in under-fill layers that may be bonding an IC chip to another chip and/or to an IC packaging substrate.

Another aspect of the present disclosure is a circuit in an IC device for detecting smaller and early stages of failures in under-fill layers that may be bonding an IC chip to another chip and/or to an IC packaging substrate.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure some technical effects may be achieved in part by a method including providing a top plate having an upper surface and a lower surface, the lower surface bonded by a bonding material layer to an upper surface of a bottom plate; forming transmitter and receiver asymmetric coupling capacitors between the top plate and the bottom plate; forming a transmission line in the bottom plate connecting elements of the transmitter and receiver asymmetric coupling capacitors in the bottom plate; and detecting a failure in the bonding material layer based, at least in part, on electrical characteristics associated with the transmitter asymmetric coupling capacitor, the receiver asymmetric coupling capacitor, the transmission line or a combination thereof.

One aspect includes determining the electrical characteristics based, at least in part, on variations in capacitance, leakage current, or a combination thereof associated with the transmitter or receiver asymmetric coupling capacitors. In another aspect, determining the electrical characteristics is based, at least in part, on variations in data transfers through the transmission line.

In some aspects, forming the transmitter asymmetric coupling capacitor includes forming a top transmitter element at the lower surface of the top plate and a bottom transmitter element at the upper surface of the bottom plate. In one aspect, forming the receiver asymmetric coupling capacitor includes forming a top receiver element at the lower surface of the top plate and a bottom receiver element at the upper surface of the bottom plate.

Another aspect includes forming the top transmitter and receiver elements in a metal layer of the top layer; and forming the bottom transmitter and receiver elements in a metal layer of the bottom plate. Some aspects include forming a test system interface in the top plate including test pads electrically coupled to each element of the transmitter and receiver asymmetric coupling capacitors in the top plate.

In one aspect, the top plate is a silicon layer and in another aspect, the bottom plate is a substrate layer or another silicon layer. In some aspects, the failure in the bonding material layer includes a delamination, a void, a crack or a combination thereof.

According to the present disclosure, some technical effects may be achieved in part by a semiconductor device including: a top plate having an upper surface and a lower surface, the lower surface bonded by a bonding material layer to an upper surface of a bottom plate; transmitter and receiver asymmetric coupling capacitors between the top plate and the bottom plate; a transmission line in the bottom plate connecting elements of the transmitter and receiver asymmetric coupling capacitors in the bottom plate; and a test system interface in the top plate including test pads electrically coupled to each element of the transmitter and receiver asymmetric coupling capacitors in the top plate.

In some aspects, the transmitter asymmetric coupling capacitor includes a top transmitter element at the lower surface of the top plate and a bottom transmitter element at the upper surface of the bottom plate. In another aspect, the receiver asymmetric coupling capacitor includes a top receiver element at the lower surface of the top plate and a bottom receiver element at the upper surface of the bottom plate.

In one aspect, the top transmitter and receiver elements are formed in a metal layer of the top layer, and the bottom transmitter and receiver elements are formed in a metal layer of the bottom plate. In a further aspect, the top plate is a silicon layer. In some aspects, the bottom plate is a substrate layer or another silicon layer.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B schematically illustrate examples of a 3D IC chip stack and a single IC chip device, respectively, bonded to a substrate;

FIGS. 2A and 2B schematically illustrate an IC chip device and included circuitry, respectively, for detecting failures in an under-fill layer in an IC device, in accordance with exemplary embodiments; and

FIG. 3 includes a diagram illustrating data points of measurements associated with an IC device.

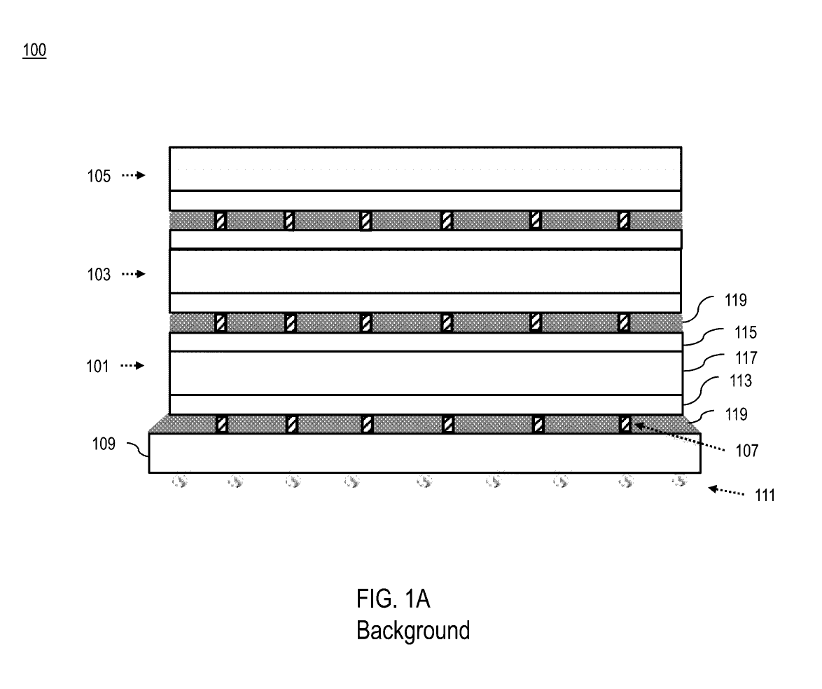

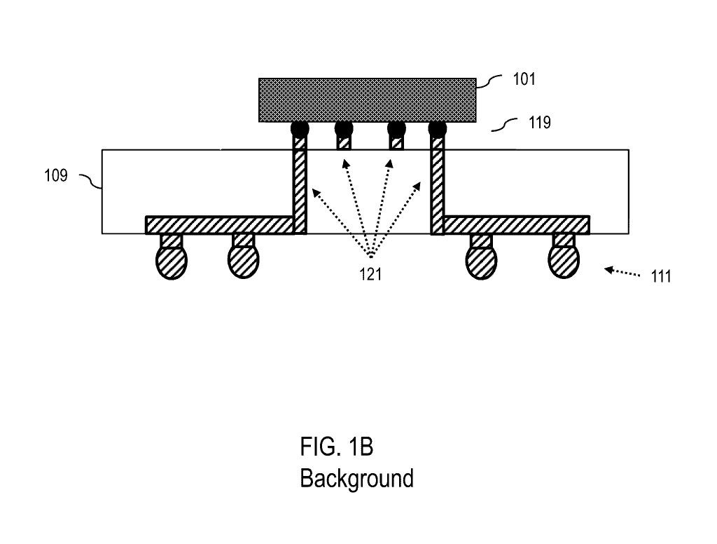

### DETAILED DESCRIPTION

For the purposes of clarity, in the following description, numerous specific details are set forth to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the problem of detecting early failures/defects in under-fill layers in various IC chip assemblies and packages, where these defects may be due to insufficient under-fill material, cracked under-fill layer, or delamination of the under-fill layer from a silicon layer or from a substrate layer with various surface finish conditions. The present disclosure addresses and solves such problems, for instance, by, inter alia, implementing a circuit in an IC device and measuring various electrical parameters associated with the IC device without causing damage to the IC device.

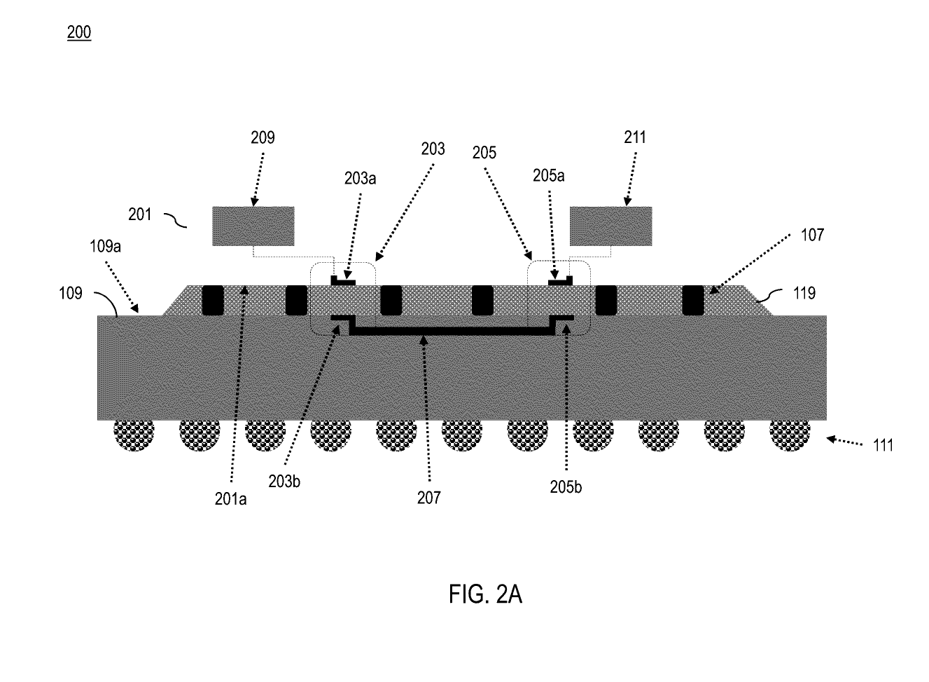

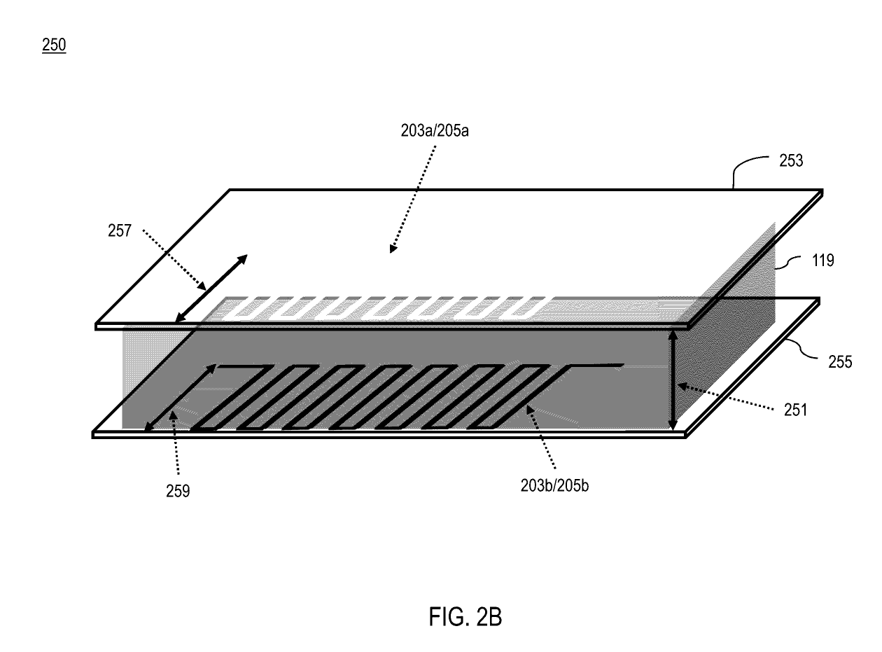

FIG. 2A schematically illustrates an IC chip device including circuitry for detecting failures in an under-fill layer in an IC device, in accordance with an exemplary embodiment. In FIG. 2A, structure 200 includes an IC chip 201 that is connected (e.g., electrical connectivity) to a substrate layer 109 by a plurality of interconnecting elements 107. Additionally, bonding material layer 119 is utilized to further bond the chip 201 to the substrate 109 by under-filling the space between the chip 201 and the substrate 109. The under-fill process may include capillary under-fill (CUF), no-flow under-fill (NUF), molded under-fill (MUF), non-conductive paste (NCP), non-conductive film (NCF), or the like, which may be applied to 2D/2.5D/3D for chip-to-substrate (C2S), chip-to-chip (C2C), chip-to-wafer (C2W), and wafer-to-wafer (W2W). For detecting defects in the under-fill layer 119, a circuitry may be implemented in the structure 200, where the circuitry may include a transmitter asymmetric coupling capacitor (transmitter capacitor) 203, a receiver asymmetric coupling capacitor (receiver capacitor) 205, and a transmission line 207 connecting the transmitter capacitor to the receiver capacitor. An asymmetric coupling capacitor may be formed by implementing an upper capacitor terminal; e.g., 203a or 205a, in a top metal (e.g., aluminum or copper) layer of the silicon layer 201 such as an IC chip, wherein the top metal layer may be on an active side of the IC chip, which may be on bottom side 201a of the silicon layer 201 as depicted. Also, a lower capacitor terminal; e.g., 203b or 205b, may be formed in a top metal (e.g., copper) layer on upper side 109a of the substrate 109. Moreover, a transmission line 207 (e.g., at 50 Ohms) in the substrate 109 may connect the lower capacitor terminals 203b and 205b. A transmitter 209 in the chip 201 may be connected to the upper transmitter capacitor terminal 203a, while a receiver 211 in the chip 201 is connected to the upper receiver capacitor terminal 205a. The transmitter 209 may include a three-stage inverter (e.g., logic gates formed by using p-type and n-type metal-oxide-semiconductor transistors) where faster first and second stage inverters and a slower third stage inverter may generate test signals so that a test system may determine capacitive effects associated with the capacitors 203 and 205. Similarly, the receiver 211 may include a three-stage inverter where first and second stage inverters may be slower than a third stage inverter. In one example, data may be transmitted from the transmitter 209 to the receiver 211 through the transmitter capacitor 203, the transmission line 207, and the receiver capacitor 205. It is noted that although FIG. 2A illustrates a test circuit with only two capacitors, a plurality of such circuits may be implemented in an IC device for detecting failures in different areas of an under-fill layer. For example, test circuits may be implemented in areas (e.g., including certain IC elements, close to an edge, etc.) with high potentials for under-fill failures.

FIG. 2B illustrates a structure of a transmitter or receiver capacitor 203/205. Diagram 250 depicts a segment of the under-fill material layer 119, at a thickness of 251 (e.g., 40 micro-meter (um)), which is between a metal layer 253 of the top plate 201 (e.g., a silicon layer) and a metal layer 255 of the bottom plate 109 (e.g., a substrate layer). Also shown, is an upper capacitor terminal, 203a or 205a, of the transmitter/receiver capacitor, 203 or 205, implemented in the metal layer 253 and a lower capacitor terminal, 203b or 205b, of the transmitter/receiver capacitor, 203 or 205, implemented in the metal layer 255. As shown, the upper capacitor terminal may be in a shape of a serpentine, for example with dimensions of a width 257 at 1.8 um, a thickness of 2.6 um, and a length of 9497.6 um, where the dimensions would yield an area of 83588.24 um². Similarly, the lower capacitor terminal may be in a shape of a serpentine, for example with dimensions of a width 259 at 15 um, a thickness of 15 um, and a length of 9497.6 um, where the dimensions would yield an area of 570306 um². The under-fill dimensions include a thickness of 40 um, permittivity of 3.8, and a loss tangent of 0.008. The asymmetric coupling capacitor calculations may be based on a capacitance of the top-plate at 70.31 femto-Farad (fF), and a capacitance of the bottom-plate at 479.7 fF that would yield a total capacitance of an asymmetric coupling capacitor at 61.32 fF.

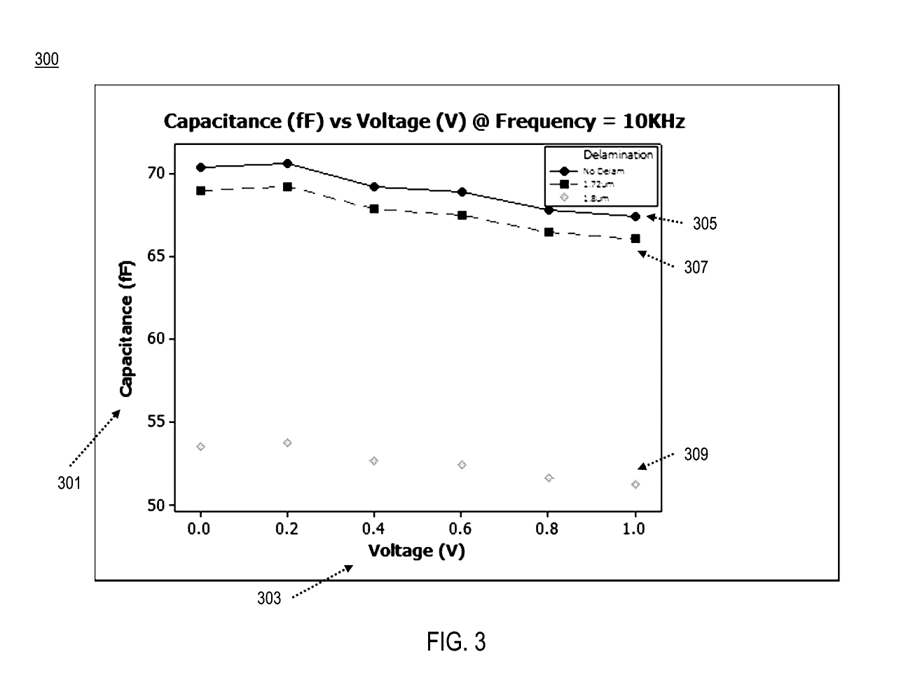

FIG. 3 includes a diagram illustrating data points of measurements associated with an IC device. In diagram 300, the data points are plotted based on capacitance vs. voltage at a given frequency, where the capacitance is along the y-axis 301 while the voltage 303 is along the x-axis of the diagram. A test system may apply a voltage at a given frequency to the transmitter 209 or receiver 211 of FIG. 2A and measure the capacitance at the respective transmitter or receiver capacitor 203 or 205. To measure the capacitance, for example, the upper and lower terminals 203a and 203b of the capacitor 203 may be connected to test pads or BGA elements 111, which may be connected to terminals (e.g., high and low) of a multi-meter for measuring the capacitance of the capacitor 203. Plot line 305 includes measurement points of capacitance vs. voltage at a frequency of 10 KHz; however, the frequency may be in the range of 10 KHz to 100 KHz. This plot line 305 is representative of an IC device, which has no failures (e.g., delamination) in areas of an under-fill layer where test capacitors, e.g., 203 or 205 of FIG. 2A, are implemented. However, data points in plot lines 307 and 309 that are associated with the same IC device, as in plot 305, are different and indicate potential delaminations of different sizes in the under-fill layer. Although these plot lines indicate delamination failures, similar measurements of capacitance vs. voltage may indicate other failures such as a void or crack in the under-fill layer. For example, a low capacitance measurement (e.g., less than 70.31 fF) may indicate a void due to an air-gap in the under-fill layer (e.g., permittivity of air is 1, which is less than the under-fill permittivity of 3.8), where capacitance is directly proportional to the permittivity of the dielectric material 119 and areas of upper and lower terminals (e.g., 203a and 203b) of a capacitor (e.g., 203), and is inversely proportional to the distance (e.g., 251) between the two terminals. In another example, a high leakage current in a capacitor (e.g., 203) may indicate a delamination in the under-fill layer in the area of the capacitor. A failure in the under-fill layer may cause errors in transmission of data from the transmitter to the receiver, where the failure may be evidenced by disturbances in a graphical representation of the data transmission or a comparison of the sent and received data.

In the example failure illustrated by the plot line 309 in FIG. 3, where there is a delamination in the form of a crack in the size of 1.8 um, asymmetric coupling capacitor calculations include capacitance of the top-plate at 60.26 fF, capacitance of the bottom-plate at 479.7 fF, and a total capacitance of asymmetric coupling capacitor (C_{T}) at 53.53 fF, which indicate a net change in capacitance of 14.3%/10.05 fF. Based on the above measurements, a minimum delamination size that may be detected may be 1.72 um (e.g., change in capacitance at 1.4%/1 fF), which is illustrated by the plot line 307 in FIG. 3.

Advantages of the proposed methods and circuitry include a design structure that may be easy to standardize or generate through a cell package in any technology node. Also, it may be easy to implement during technology qualification and process/reliability monitoring. Additionally, early stages of defects in under-fill layers may be detected in early package assembly process or reliability tests with fast cycle time for feedback. Moreover, no extra mask, metal layer, or test infrastructure may be needed.

The embodiments of the present disclosure can achieve several technical effects, including implementation of a circuit in an IC device for measuring various electrical parameters for detecting smaller and early stages of failures in under-fill layers that may be bonding an IC chip to another chip and/or to an IC packaging substrate. Furthermore, the embodiments enjoy utility in various industrial applications as, for example, microprocessors, smart phones, mobile phones, cellular handsets, set-top boxes, DVD recorders and players, automotive navigation, printers and peripherals, networking and telecom equipment, gaming systems, digital cameras, or other devices utilizing logic or high-voltage technology nodes. The present disclosure therefore enjoys industrial applicability in any of various types of highly integrated semiconductor devices, including devices that use static-random-access memory (SRAM) cells (e.g., liquid crystal display (LCD) drivers, digital processors, etc.)

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a top plate having an upper surface and a lower surface, the lower surface bonded by a bonding material layer to an upper surface of a bottom plate;
forming transmitter and receiver asymmetric coupling capacitors between the top plate and the bottom plate;
forming a transmission line in the bottom plate connecting elements of the transmitter and receiver asymmetric coupling capacitors in the bottom plate; and
detecting a failure in the bonding material layer based, at least in part, on electrical characteristics associated with the transmitter asymmetric coupling capacitor, the receiver asymmetric coupling capacitor, the transmission line or a combination thereof.

2. The method according to claim 1, further comprising:
determining the electrical characteristics based, at least in part, on variations in a capacitance, a leakage current, or a combination thereof associated with the transmitter or receiver asymmetric coupling capacitors.

3. The method according to claim 1, further comprising:
determining the electrical characteristics based, at least in part, on variations in a data transfer through the transmission line.

4. The method according to claim 1, wherein forming the transmitter asymmetric coupling capacitor comprises:
forming a top transmitter element at the lower surface of the top plate and a bottom transmitter element at the upper surface of the bottom plate.

5. The method according to claim 4, wherein forming the receiver asymmetric coupling capacitor comprises:
forming a top receiver element at the lower surface of the top plate and a bottom receiver element at the upper surface of the bottom plate.

6. The method according to claim 5, further comprising:
forming the top transmitter and receiver elements in a metal layer of the top layer; and
forming the bottom transmitter and receiver elements in a metal layer of the bottom plate.

7. The method according to claim 1, further comprising:
forming a test system interface in the top plate including test pads electrically coupled to each element of the transmitter and receiver asymmetric coupling capacitors in the top plate.

8. The method according to claim 1, wherein the top plate is a silicon layer.

9. The method according to claim 1, wherein the bottom plate is a substrate layer or another silicon layer.

10. The method according to claim 1, wherein the failure in the bonding material layer includes a delamination, a void, a crack or a combination thereof.

11. A semiconductor device comprising:
a top plate having an upper surface and a lower surface, the lower surface bonded by a bonding material layer to an upper surface of a bottom plate;
transmitter and receiver asymmetric coupling capacitors between the top plate and the bottom plate;
a transmission line in the bottom plate connecting elements of the transmitter and receiver asymmetric coupling capacitors in the bottom plate; and
a test system interface in the top plate including test pads electrically coupled to each element of the transmitter and receiver asymmetric coupling capacitors in the top plate.

12. The semiconductor device according to claim 11, wherein the transmitter asymmetric coupling capacitor comprises:
a top transmitter element at the lower surface of the top plate and a bottom transmitter element at the upper surface of the bottom plate.

13. The semiconductor device according to claim 12, wherein the receiver asymmetric coupling capacitor comprises:
a top receiver element at the lower surface of the top plate and a bottom receiver element at the upper surface of the bottom plate.

14. The semiconductor device according to claim 13, wherein the top transmitter and receiver elements are formed in a metal layer of the top layer, and the bottom transmitter and receiver elements are formed in a metal layer of the bottom plate.

15. The semiconductor device according to claim 11, wherein the top plate is a silicon layer.

16. The semiconductor device according to claim 11, wherein the bottom plate is a substrate layer or another silicon layer.

17. A method comprising:
providing a top plate having an upper surface and a lower surface, the lower surface bonded by a bonding material layer to an upper surface of a bottom plate, wherein the top plate is a silicon layer and the bottom plate is a substrate layer or another silicon layer;
forming transmitter and receiver asymmetric coupling capacitors between the top plate and the bottom plate;
forming a transmission line in the bottom plate connecting elements of the transmitter and receiver asymmetric coupling capacitors in the bottom plate;
determining electrical characteristics based, at least in part, on variations in a capacitance, a leakage current, or a combination thereof associated with the transmitter or receiver asymmetric coupling capacitors; and
detecting a failure in the bonding material layer based, at least in part, on the electrical characteristics.

18. The method according to claim 1, further comprising:
determining the electrical characteristics based, at least in part, on variations in a data transfer through the transmission line.

19. The method according to claim 1, further comprising:
forming a top transmitter element in a metal layer at the lower surface of the top plate and a bottom transmitter element in a metal layer at the upper surface of the bottom plate; and
forming a top receiver element in the metal layer at the lower surface of the top plate and a bottom receiver element in the metal layer at the upper surface of the bottom plate.

20. The method according to claim 1, further comprising:
forming a test system interface in the top plate including test pads electrically coupled to each element of the transmitter and receiver asymmetric coupling capacitors in the top plate.
